(19) United States
(12) Patent Application Publication
(10) Pub. No.: US 2025/0210528 A1
(43) Pub. Date: Jun. 26, 2025

(54) SYSTEMS AND METHODS FOR 3D INTEGRATION

(71) Applicant: Meta Platforms Technologies, LLC, Menlo Park, CA (US)

(72) Inventors: Rajendra D Pendse, Fremont, CA (US); Jaspreet Singh Gandhi, San Jose, CA (US)

(21) Appl. No.: 18/391,000

(22) Filed: Dec. 20, 2023

(51) Int. Cl. H01L 23/538; H01L 21/48; H01L 23/00; H01L 23/498

(52) U.S. Cl. CPC H01L 23/5383; H01L 21/4857; H01L 23/49816; H01L 24/16; H01L 2224/16227

(57) ABSTRACT

A method for 3D integration may include forming a first layer of packaging laminate substrate material including a first plurality of vias formed therein. The method may additionally include forming a second layer of packaging laminate substrate material having a second plurality of vias formed therein. The method may also include stacking the first plurality of vias with the second plurality of vias. Various other methods, systems, and computer-readable media are also disclosed.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for 3D integration.

FIG. 2 is an illustration of exemplary semiconductor device packages for 3D integration.

FIG. 3 is an illustration of an exemplary semiconductor device package for 3D integration.

FIG. 4 is an illustration of an exemplary semiconductor device package for 3D integration.

FIG. 5 is an illustration of an exemplary semiconductor device package for 3D integration.

FIG. 6 is an illustration of exemplary augmented-reality glasses that may be used in connection with embodiments of this disclosure.

FIG. 7 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

A three-dimensional integrated circuit (3D IC) is a MOS (metal-oxide semiconductor) integrated circuit (IC) manufactured by stacking as many as sixteen or more ICs and interconnecting them vertically using, for instance, through-silicon vias (TSVs) or Cu—Cu connections, so that they behave as a single device to achieve performance improvements at reduced power and smaller footprint than conventional two dimensional processes. The 3D IC is one of several 3D integration schemes that exploit the z-direction to achieve electrical performance benefits in microelectronics and nanoelectronics.

3D integrated circuits may be classified by their level of interconnect hierarchy at the global (package), intermediate (bond pad) and local (transistor) level. In general, 3D integration is a broad term that includes such technologies as 3D wafer-level packaging (3DWLP), 2.5D and 3D interposer-based integration, 3D stacked ICs (3D-SICs), 3D heterogeneous integration, and 3D systems integration as well as true monolithic 3D ICs.

3D integrated circuit manufacture processes build one semiconductor layer (e.g., die or wafer) atop another. Example stacking procedures may include die-to-die stacking, die-to-wafer stacking, and/or wafer-to-wafer stacking. In die-to-die stacking, electronic components are built on multiple die that are then aligned and bonded to one another. In die-to-wafer stacking, electronic components are built on two or more semiconductor wafers; one wafer is diced, and the resulting die are then aligned and bonded onto die sites of the other wafer. In wafer to wafer stacking, electronic components are built on two or more semiconductor wafers that are then aligned, bonded, and diced into 3D integrated circuits.

Partitioning is a process of dividing a chip into smaller blocks. This partitioning is performed mainly to separate different functional blocks and also to make placement and routing easier. Partitioning may be performed in the RTL design phase when the design engineer partitions the entire design into sub-blocks and then proceeds to design each module. These modules may be linked together in a main module called a TOP LEVEL module. This kind of partitioning is commonly referred to as Logical Partitioning. A goal of partitioning is to split the circuit such that the number of connections between partitions is minimized.

A system on a chip or system-on-chip (SoC) is an integrated circuit that integrates most or all components of a computer or other electronic system. These components almost always include on-chip central processing unit (CPU), memory interfaces, input/output devices and interfaces, and secondary storage interfaces, often alongside other components such as radio modems and a graphics processing unit (GPU)—all on a single substrate or microchip. With an SoC, a chip might incorporate a CPU, plus an additional one-hundred IP blocks on the same chip. That design is then scaled by moving to the next node, which is an expensive process. With a chiplet model, those one-hundred IP blocks are hardened into smaller dies or chiplets.

The present disclosure is generally directed to systems and methods for 3D integration. As will be explained in greater detail below, embodiments of the present disclosure may form a first layer of packaging laminate substrate material including a first plurality of vias formed therein, form a second layer of packaging laminate substrate material having a second plurality of vias formed therein, and stack the first plurality of vias with the second plurality of vias. In some implementations, the first plurality of vias and the second plurality of vias may have a pitch in a range of forty to eighty micrometers. For example, the first plurality of vias and the second plurality of vias may have a pitch no greater than eighty micrometers or, in some implementations, no greater than fifty micrometers. Additionally or alternatively, individual vias of the first plurality of vias and the second plurality of vias may have a size in a range of ten to forty micrometers. For example, the individual vias may have a size no greater than forty micrometers or, in some implementations, no greater than twelve micrometers. Additionally or alternatively, via pads corresponding to the individual vias may have a size in a range of twenty-five to sixty micrometers. For example, the via pads may have a size no greater than sixty micrometers or, in some implementations, no greater than twenty-five micrometers. Still other implementations may have narrower ranges of via pitch (e.g., forty to seventy micrometers, forty to sixty micrometers, forty to fifty micrometers, etc.), individual via size (e.g., ten to thirty micrometers, ten to twenty micrometers, ten to twelve micrometers, etc.), and via pad size (e.g., twenty-five to fifty micrometers, twenty-five to forty micrometers, twenty-five to thirty micrometers, etc.). A resulting semiconductor device packaging medium may provide numerous benefits and capabilities.

Benefits and capabilities arising from the semiconductor device packaging medium may include the capability to bond two systems on chip (SOCs) face to face with fine pitch interconnects resulting in smaller die to die (D2D) channel length, shorter signal escape, and/or power delivery routes. Si partitioning and chipletization performed in this manner may accommodate high functionality, block density with smaller form factor, and/or low latency and high bandwidth. The fine via stack (FVS) laminate may provide a benefit of cost and cycle time reduction compared to use of a redistribution layer (RDL) performed in fanout technology as the packaging medium between the two SOCs. In some implementations, a first SOC may include an anchor die having a two by two millimeter die to die interface in a center thereof for direct via to via connection to a second SOC.

In some implementations, the second SOC may correspond to a smaller chiplet (e.g., smaller in area than the anchor die). In some implementations, the smaller chiplet may have a majority of power thereof supplied though the first SOC. Alternatively or additionally, the smaller chiplet may have a direct supply through a ball grid array pad. In certain implementations, via size may be in a range of ten to forty micrometers, via pad size may be in a range of twenty-five to sixty micrometers, and via to via pitch may be in a range of forty to eighty micrometers. For example, via size may correspond to approximately forty micrometers, via pad size may correspond to approximately sixty micrometers, pad to pad distance may correspond to approximately twenty micrometers, and via to via pitch may correspond to approximately eighty micrometers. In other implementations, the via pitch may correspond to approximately fifty micrometers, the individual via size may correspond to approximately ten to twelve micrometers, and the via pad size may correspond to approximately twenty-five micrometers. Further benefits achieved by the disclosed systems and methods may include reduction in cost (e.g., fourteen USD instead of twenty-two USD) and reduction in packaging cycle time (e.g., four to six weeks instead of twenty weeks).

Features from any of the embodiments described herein may be used in combination with one another in accordance with the general principles described herein. These and other embodiments, features, and advantages will be more fully understood upon reading the following detailed description in conjunction with the accompanying drawings and claims.

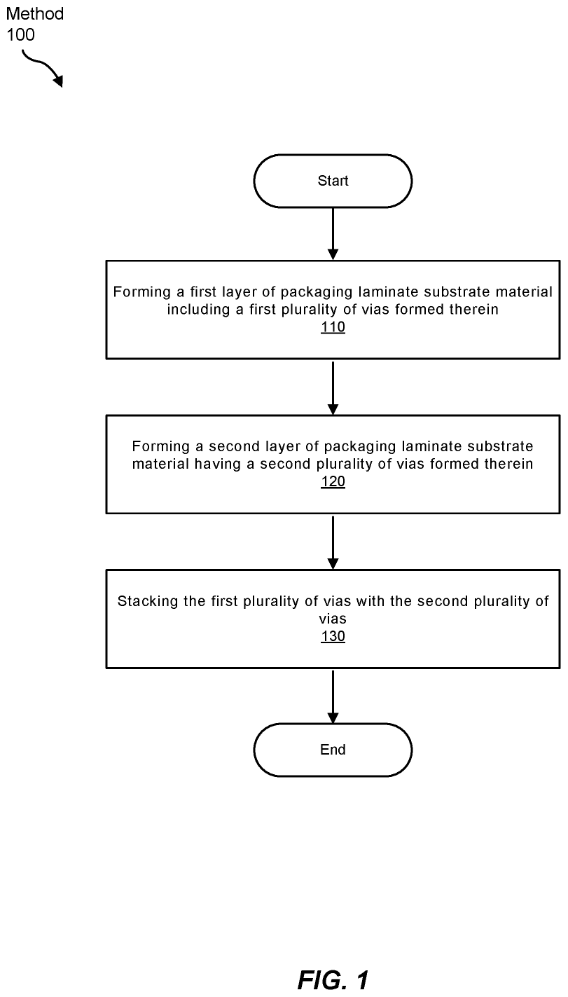

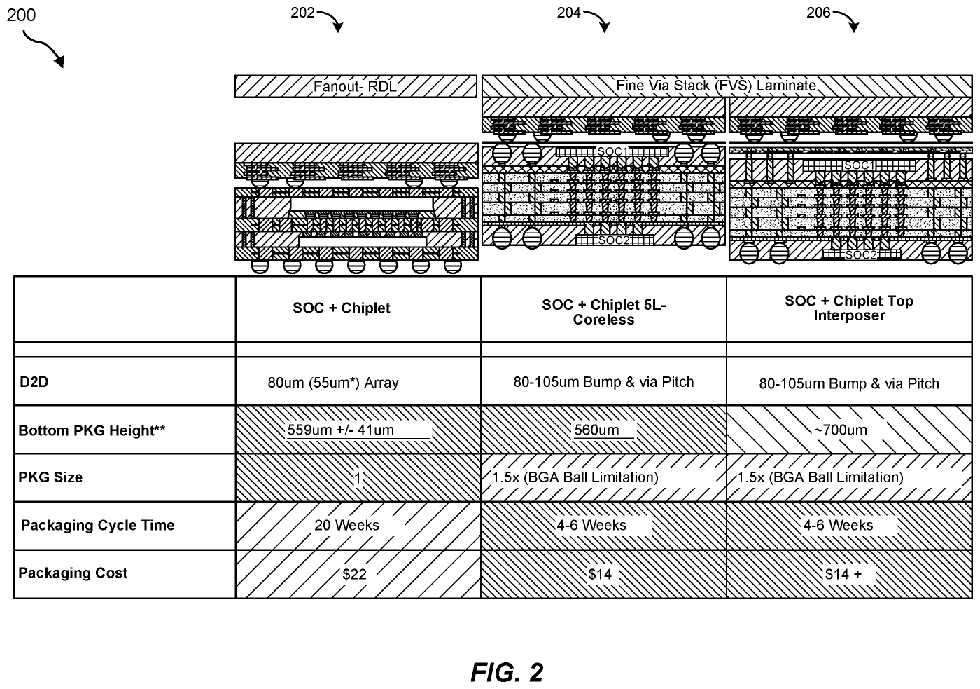

The following will provide, with reference to FIG. 1, detailed descriptions of an exemplary method for 3D integration. Detailed descriptions of exemplary semiconductor device packages for 3D integration will be provided in connection with FIGS. 2-5. Additionally, detailed descriptions of exemplary augmented-reality glasses and virtual-reality headsets will be provided with reference to FIGS. 13 and 14.

FIG. 1 is a flow diagram of an exemplary method 100 for 3D integration. Beginning at step 110, method 100 may include forming a first layer. For example, step 110 may include forming a first layer of packaging laminate substrate material including a first plurality of vias formed therein.

The term “packaging laminate substrate material,” as used herein, may generally refer to multiple, thin layers of material stacked to form a rigid substrate. For example, and without limitation, packaging laminate substrate material may be made of stacked layers that correspond to epoxy (e.g., FR4) and/or resin (e.g., bismaleimide-triazine (BT)). In this context, “substrate” may generally refer to a part of a semiconductor device package that gives the board its mechanical strength and allows it to connect with external devices.

The term “via,” as used herein, may generally refer to an electrical connection. For example, and without limitation, a via may correspond to an electrical connection between different layers of a printed circuit board. Such a via may correspond to a small hole made through the PCB laminates that crosses two or more adjacent layers. Such a via may also be plated or filled with an electrically conductive material, such as metal (e.g., copper).

The term “formed,” as used herein, may generally refer to laser drilling and/or lithography. For example, and without limitation, vias may be formed in a packaging laminate substrate material by laser drilling and or photolithography. In this context, CO2 laser drilling may form individual vias having a size in a range of forty to sixty micrometers. Alternatively, UV laser followed by excimer laser may drill even smaller individual vias. Moreover, lithography based photo vias may have a size of ten micrometers or less.

Step 110 may be performed in a variety of ways. In one example, the first plurality of vias may have a pitch in a range of forty to eighty micrometers. For example, via pitch may be no greater than eighty micrometers. Alternatively or additionally, individual vias of the first plurality of vias may have a size in a range of ten to forty micrometers. For example, individual via size may be no greater than forty micrometers. Alternatively or additionally, the individual vias of the first plurality of vias may have corresponding via pads each having a size in a range of twenty-five to sixty micrometers. For example, the via pads may have a size no greater than sixty micrometers. In another example, the via pitch may correspond to approximately fifty micrometers, the individual via size may correspond to approximately ten to twelve micrometers, and the via pad size may correspond to approximately twenty-five micrometers.

At step 120, method 100 may include forming a second layer. For example, step 120 may include forming a second layer of packaging laminate substrate material having a second plurality of vias formed therein.

Step 120 may be performed in a variety of ways. In one example, the second plurality of vias may have a pitch in a range of forty to eighty micrometers. For example, the via pitch may be no greater than eighty micrometers. Alternatively or additionally, individual vias of the second plurality of vias may have a size in a range of ten to forty micrometers, For example, individual vias may have a size no greater than forty micrometers. Alternatively or additionally, the individual vias of the second plurality of vias may have corresponding via pads each having a size in a range of twenty-five to sixty micrometers. For example, the via pads may have a size no greater than sixty micrometers. In another example, the via pitch may correspond to approximately fifty micrometers, the individual via size may correspond to approximately ten to twelve micrometers, and the via pad size may correspond to approximately twenty-five micrometers.

At step 130, method 100 may include stacking vias. For example, step 130 may include stacking the first plurality of vias with the second plurality of vias.

The term “stacking,” as used herein, may generally refer to vertically arranging two or more layers of material one atop another. For example, and without limitation, multiple layers of organic substrate material may be stacked vertically using, for example, laser drilled vias and/or photo vias enabling copper to copper (Cu—Cu) connections.

Step 130 may be performed in a variety of ways. In one example, the stacking may produce a semiconductor device packaging medium that includes or corresponds to a packaging laminate substrate. Additionally or alternatively, the stacking may configure a via stack that includes the first plurality of vias and the second plurality of vias. In some implementations, this via stack may be configured to connect a first system on chip positioned on a first side of the semiconductor device packaging medium to a second system on chip positioned on a second side of the semiconductor device packaging medium that is opposite the first side. Additionally or alternatively, the stacking may also produce a packaging laminate substrate that includes a plurality of peripheral stack vias configured to supply power and input-output routing to the first system on chip and the second system on chip.

In some implementations, step 130 may include employing the packaging laminate substrate in a semiconductor device package. For example, step 130 may include positioning the packaging laminate substrate between the first system on chip and the second system on chip such that the via stack provides direct via to via connection of the first system on chip to the second system on chip. In some of these implementations, the first system on chip may be bonded face-to-face with the second system on chip with the via stack providing direct via to via connection therebetween. Alternatively or additionally, the first system on chip may correspond to an anchor die and the second system on chip may correspond to a chiplet that is smaller in area compared to the anchor die. In some of these implementations, the chiplet may have a majority of power thereof supplied by the anchor die. Alternatively or additionally, the chiplet may have a direct power supply through a ball grid array pad.

The term “anchor die,” as used herein, may generally refer to a chiplet that may provide one or more services and/or support for one or more other chiplets. For example, and without limitation, an anchor die may correspond to a chiplet that may provide configuration, management, and test services and/or may support multiple chiplets on one or more of its die edges.

Si partitioning and chipletization, especially in 3D, has an immense value proposition in the consumer electronic world to accommodate high functionality, block density with smaller form factor, low latency, and high bandwidth. The disclosed systems and methods may accomplish a 3D partitioned SOC-DRAM package structure in which two SOC may be bonded face to face with fine pitch interconnects resulting in smaller D2D channel length, shorter signal escape, and shorter power delivery routes. For example, a packaging medium between the two SOCs may include a fine via stack (FVS) laminate that may achieve cost and cycle time reduction compared to use of a redistribution layer (RDL) typically performed in fanout technology.

FIG. 2 illustrates exemplary semiconductor device packages 200 for 3D integration. For example, a fanout package 202 is shown in comparison with packages 204 and 206 that utilize a fine via stack laminate as a packaging medium between two SoCs. The fanout package may achieve a smaller footprint compared to that of the packages 204 and 206, but it does so at the expense of significantly increased costs (twenty-two USD) and packaging cycle time (e.g., twenty weeks). In comparison, the packages 204 and 206 that utilize a fine via stack laminate as a packaging medium between two SoCs achieve significantly decreased cost (e.g., fourteen USD) and packaging cycle time (e.g., four to six weeks) while remaining sufficiently small in package area and package height to meet form factor requirements for many applications (e.g., VR headsets).

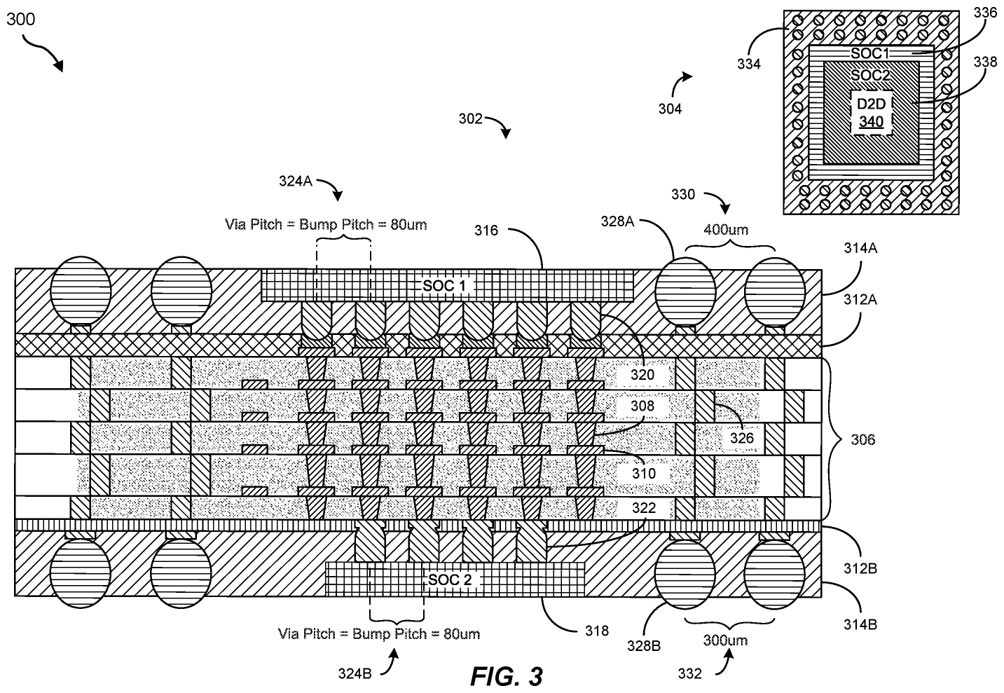

FIG. 3 illustrates an exemplary semiconductor device package 300 for 3D integration that may be formed according to the method of FIG. 1 and/or correspond to the package 204 of FIG. 2. For example, package layers 302 and package layout 304 are shown. Among the package layers 302 may include a fine via stack laminate 306 that includes two or more layers (e.g., three layers (3L), five layers (5L), etc.). Each of the layers may include a plurality of vias 308 having corresponding via pads 310. In one example, the individual vias 308 may have a size (e.g., diameter) in a range of ten to forty micrometers. For example, the individual vias may have a size of forty micrometers. Additionally, the pads 310 may have a size (e.g., diameter) in a range of twenty-five to sixty micrometers. For example, the via pads 310 may have a size of sixty micrometers. In another example, the individual via size may correspond to approximately ten to twelve micrometers, and the via pad size may correspond to approximately twenty-five micrometers. The pluralities of vias may stack with one another to form the fine via stack of the laminate 306. Dielectric material layers 312A and 312B may be arranged above and below the fine via stack laminate 306 and mold material 314A and 314B may be arranged above and below the dielectric material layers 312A and 312B.

As shown in FIG. 3, first SoC 316 and a second SoC 318 may have bumps 320 and 322 and be situated in the mold material 314A and 314B as shown. For example, the first SoC 316 may be held in place by mold material 314A on one side of the fine via stack laminate 306 with its bumps 320 in contact with the pads corresponding to vias of the fine via stack laminate 306. Similarly, the second SoC 318 may be held in place by mold material 314B on an opposite side of the fine via stack laminate 306 with its bumps 322 in contact with the fine via stack of laminate 306. Accordingly, bumps 320, vias 308, pads 310, and bumps 322 may all have a same pitch 324A and 324B, which may be in a range of forty to eighty micrometers. For example, the same pitch 324A and 324B may be eighty micrometers or fifty micrometers.

As shown in FIG. 3, the fine via stack laminate 306 may include a plurality of peripheral stack vias 326 configured to supply power and input-output routing to the first SoC 316 and the second SoC 318. These peripheral stack vias 326 may have corresponding balls of ball grid arrays 328A and 328B at least partially enclosed by the mold material 314A and 314B. For example, ball grid array 328A may have a pitch 330 of four hundred micrometers and ball grid array 328B may have a pitch 332 of three-hundred micrometers.

As shown in FIG. 3, package layout 304 may include a periphery 334 in which peripheral stack vias 326 and balls of BGAs 328A and 328B may be located. Package layout 304 also may include a first area 336 in which the first SoC 316 is located, a second area 338 in which the second SoC 318 is located, and a die to die interface region 340 in which the plurality of vias 308 having corresponding via pads 310 may be located. The plurality of vias 308 having corresponding via pads 310 may be located only in the die to die interface region 340, which may correspond to an area of the package smaller in size (e.g., length and width) than the first area 336 and the second area 338. Locating the plurality of vias 308 having corresponding via pads 310 only in this relatively small (e.g., two by two millimeter) die to die interface region 340 may avoid compromising structural integrity of the packaging medium.

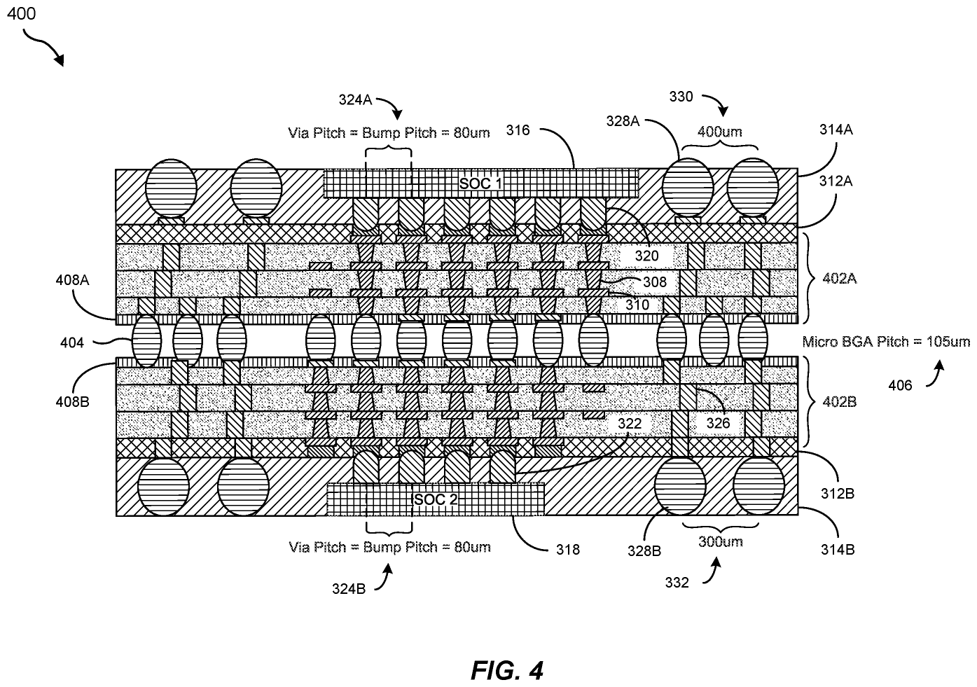

FIG. 4 illustrates an exemplary semiconductor device package 400 for 3D integration that may be formed according to the method of FIG. 1. Semiconductor device package 400 may have many features that are the same or similar to features of semiconductor device package 300 of FIG. 3, such as plurality of vias 308 having corresponding via pads 310, dielectric material layers 312A and 312B, mold material 314A and 314B, first SoC 316, second SoC 318, bumps 320 and 322, pitch 324A and 324B, peripheral stack vias 326, ball grid arrays 328A and 328B, pitch 330, and pitch 332. In addition, semiconductor device package 400 may include a first fine via stack laminate 402A that includes two or more layers (e.g., three layers (3L)) and a second fine via stack laminate 402B that includes two or more layers (e.g., three layers (3L)). Each of the layers of the first fine via stack laminate 402A and the second fine via stack laminate 402B may include a plurality of vias 308 having corresponding via pads 310. Also, semiconductor device package 400 may include one or more micro BGA 404 connecting the first fine via stack laminate 402A and the second fine via stack laminate 402B, and one or more the micro BGAs may have pitch 406 of eighty micrometers. Further, semiconductor device package 400 may include additional layers of dielectric material 408A and 408B arranged as shown.

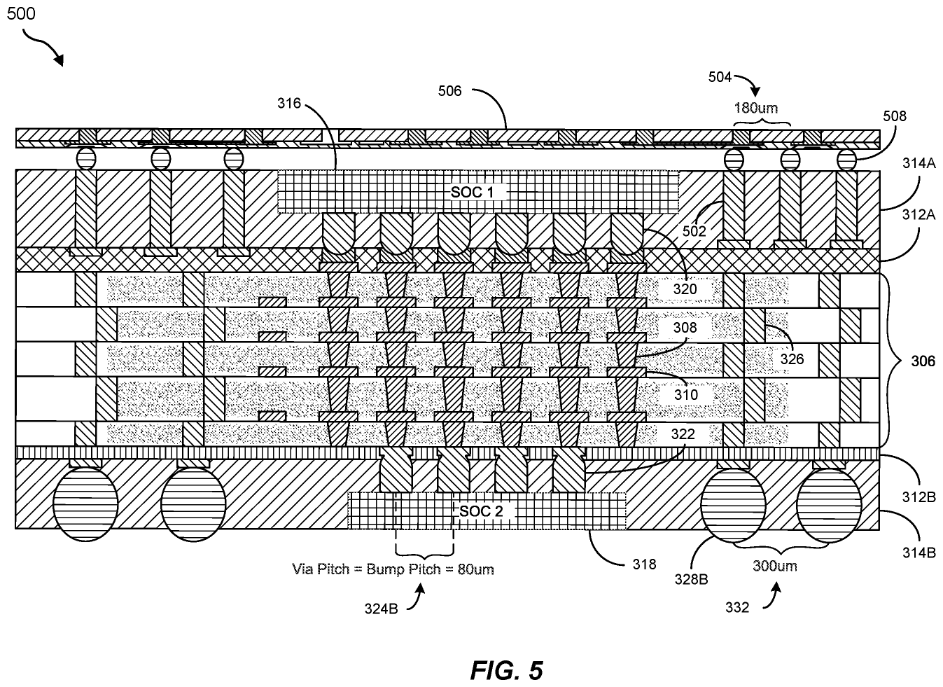

FIG. 5 illustrates an exemplary semiconductor device package 500 for 3D integration that may be formed according to the method of FIG. 1 and/or correspond to the package 206 of FIG. 2. Semiconductor device package 500 may have many features that are the same or similar to features of semiconductor device package 300 of FIG. 3, such as fine via stack laminate 306, plurality of vias 308 having corresponding via pads 310, dielectric material layers 312A and 312B, mold material 314A and 314B, first SoC 316, second SoC 318, bumps 320 and 322, pitch 324B, peripheral stack vias 326, ball grid array 328B, and pitch 332. Additionally, the peripheral stack vias 326 may have corresponding through mold vias 502 through the mold material 314A. These through mold vias 502 may have a pitch 504 of one-hundred eighty micrometers for connection to an interposer 506 by microbumps 508.

As set forth above, the disclosed systems and methods may achieve 3D integration at least in part by forming a first layer of packaging laminate substrate material including a first plurality of vias formed therein, forming a second layer of packaging laminate substrate material having a second plurality of vias formed therein, and stacking the first plurality of vias with the second plurality of vias. In some implementations, the first plurality of vias and the second plurality of vias may have a pitch in a range of forty to eighty micrometers. For example, the first plurality of vias and the second plurality of vias may have a pitch no greater than eighty micrometers or, in some implementations, no greater than fifty micrometers. Additionally or alternatively, individual vias of the first plurality of vias and the second plurality of vias may have a size in a range of ten to forty micrometers. For example, the individual vias may have a size no greater than forty micrometers or, in some implementations, no greater than twelve micrometers. Additionally or alternatively, via pads corresponding to the individual vias may have a size in a range of twenty-five to sixty micrometers. For example, the via pads may have a size no greater than sixty micrometers or, in some implementations, no greater than twenty-five micrometers. A resulting semiconductor device packaging medium may provide numerous benefits and capabilities.

Benefits and capabilities arising from the semiconductor device packaging medium may include the capability to bond two systems on chip (SOCs) face to face with fine pitch interconnects resulting in smaller die to die (D2D) channel length, shorter signal escape, and/or power delivery routes. Si partitioning and chipletization performed in this manner may accommodate high functionality, block density with smaller form factor, and/or low latency and high bandwidth. The fine via stack (FVS) laminate may provide a benefit of cost and cycle time reduction compared to use of a redistribution layer (RDL) performed in fanout technology as the packaging medium between the two SOCs. In some implementations, a first SOC may include an anchor die having a two by two millimeter die to die interface in a center thereof for direct via to via connection to a second SOC.

In some implementations, the second SOC may correspond to a smaller chiplet (e.g., smaller in area than the anchor die). In some implementations, the smaller chiplet may have a majority of power thereof supplied though the first SOC. Alternatively or additionally, the smaller chiplet may have a direct supply through a ball grid array pad. In certain implementations, via size may be in a range of ten to forty micrometers, via pad size may be in a range of twenty-five to sixty micrometers, and via to via pitch may be in a range of forty to eighty micrometers. For example, via size may correspond to approximately forty micrometers, via pad size may correspond to approximately sixty micrometers, pad to pad distance may correspond to approximately twenty micrometers, and via to via pitch may correspond to approximately eighty micrometers. In other implementations, the via pitch may correspond to approximately fifty micrometers, the individual via size may correspond to approximately ten to twelve micrometers, and the via pad size may correspond to approximately twenty-five micrometers. Further benefits achieved by the disclosed systems and methods may include reduction in cost (e.g., fourteen USD instead of twenty-two USD) and reduction in packaging cycle time (e.g., four to six weeks instead of twenty weeks).

### Example Embodiments

Example 1: A semiconductor device packaging medium may include a first layer of packaging laminate substrate material including a first plurality of vias formed therein, and a second layer of packaging laminate substrate material having a second plurality of vias formed therein, wherein the first plurality of vias stack with the second plurality of vias.

Example 2: The semiconductor device packaging medium of Example 1, wherein the first plurality of vias and the second plurality of vias have a pitch in a range of forty to eighty micrometers.

Example 3: The semiconductor device packaging medium of any of Examples 1 and 2, wherein individual vias of the first plurality of vias and the second plurality of vias have a size in a range of ten to forty micrometers.

Example 4: The semiconductor device packaging medium of any of Examples 1 to 3, wherein individual vias of the first plurality of vias and the second plurality of vias have corresponding via pads each having a size in a range of twenty-five to sixty micrometers.

Example 5: The semiconductor device packaging medium of any of Examples 1 to 4, wherein a via stack that includes the first plurality of vias and the second plurality of vias is configured to connect a first system on chip positioned on a first side of the semiconductor device packaging medium to a second system on chip positioned on a second side of the semiconductor device packaging medium that is opposite the first side.

Example 6: The semiconductor device packaging medium of any of Examples 1 to 5, further including a plurality of peripheral stack vias configured to supply power and input-output routing to the first system on chip and the second system on chip.

Example 7: The semiconductor device packaging medium of any of Examples 1 to 6, wherein the first plurality of vias and the second plurality of vias are located only in a die to die interface region that is between the first system on chip and the second system on chip and that is smaller in area than the first system on chip and the second system on chip.

Example 8: A semiconductor device package may include a first system on chip, a second system on chip, and a packaging laminate substrate positioned between the first system on chip and the second system on chip and including a via stack that is configured to provide direct via to via connection of the first system on chip to the second system on chip.

Example 9: The semiconductor device package of Example 8, wherein the via stack has a pitch in a range of forty to eighty micrometers.

Example 10: The semiconductor device package of any of Examples 8 and 9, wherein individual vias of the via stack have a size in a range of ten to forty micrometers.

Example 11: The semiconductor device package of any of Examples 8 to 10, wherein the via stack is located only in a die to die interface region that is between the first system on chip and the second system on chip and that is smaller in area than the first system on chip and the second system on chip.

Example 12: The semiconductor device package of any of Examples 8 to 11, wherein the packaging laminate substrate further includes a plurality of peripheral stack vias configured to supply power and input-output routing to the first system on chip and the second system on chip.

Example 13: The semiconductor device package of any of Examples 8 to 12, wherein the first system on chip corresponds to an anchor die and the second system on chip corresponds to a chiplet that is smaller in area compared to the anchor die.

Example 14: The semiconductor device package of any of Examples 8 to 13, wherein the chiplet has a majority of power thereof supplied by the anchor die.

Example 15: The semiconductor device package of any of Examples 8 to 14, wherein the chiplet has a direct power supply through a ball grid array pad.

Example 16: The semiconductor device package of any of Examples 8 to 15, wherein the first system on chip is bonded face-to-face with the second system on chip with the via stack providing direct via to via connection therebetween.

Example 17: A method may include forming a first layer of packaging laminate substrate material including a first plurality of vias formed therein, forming a second layer of packaging laminate substrate material having a second plurality of vias formed therein, and stacking the first plurality of vias with the second plurality of vias.

Example 18: The method of Example 17, wherein the first plurality of vias and the second plurality of vias have a pitch in a range of forty to eighty micrometers.

Example 19: The method of any of Examples 17 and 18, wherein individual vias of the first plurality of vias and the second plurality of vias have a size in a range of ten to forty micrometers.

Example 20: The method of any of Examples 17 to 19, wherein individual vias of the first plurality of vias and the second plurality of vias have corresponding via pads each having a size in a range of twenty-five to sixty micrometers.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

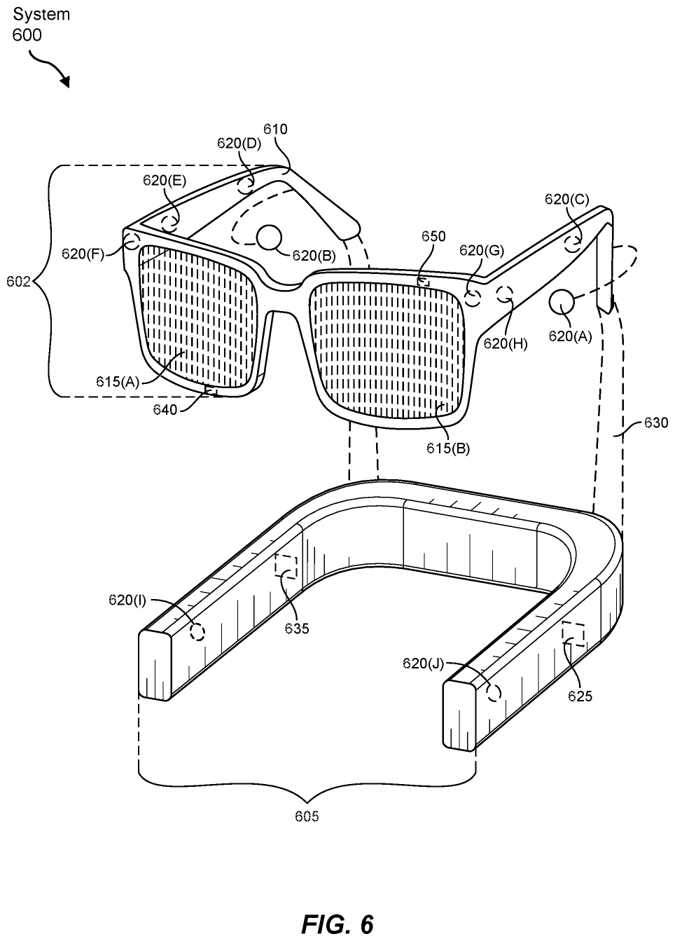

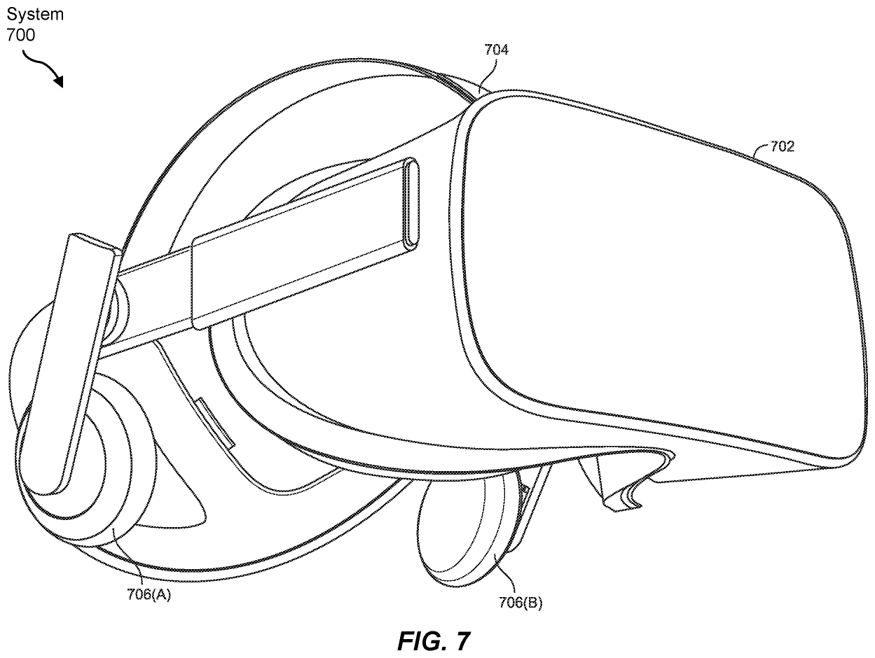

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 600 in FIG. 6) or that visually immerses a user in an artificial reality (such as, e.g., virtual-reality system 700 in FIG. 7). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 6, augmented-reality system 600 may include an eyewear device 602 with a frame 610 configured to hold a left display device 615(A) and a right display device 615(B) in front of a user's eyes. Display devices 615(A) and 615(B) may act together or independently to present an image or series of images to a user. While augmented-reality system 600 includes two displays, embodiments of this disclosure may be implemented in augmented-reality systems with a single NED or more than two NEDs.

In some embodiments, augmented-reality system 600 may include one or more sensors, such as sensor 640. Sensor 640 may generate measurement signals in response to motion of augmented-reality system 600 and may be located on substantially any portion of frame 610. Sensor 640 may represent one or more of a variety of different sensing mechanisms, such as a position sensor, an inertial measurement unit (IMU), a depth camera assembly, a structured light emitter and/or detector, or any combination thereof. In some embodiments, augmented-reality system 600 may or may not include sensor 640 or may include more than one sensor. In embodiments in which sensor 640 includes an IMU, the IMU may generate calibration data based on measurement signals from sensor 640. Examples of sensor 640 may include, without limitation, accelerometers, gyroscopes, magnetometers, other suitable types of sensors that detect motion, sensors used for error correction of the IMU, or some combination thereof.

In some examples, augmented-reality system 600 may also include a microphone array with a plurality of acoustic transducers 620(A)-620(J), referred to collectively as acoustic transducers 620. Acoustic transducers 620 may represent transducers that detect air pressure variations induced by sound waves. Each acoustic transducer 620 may be configured to detect sound and convert the detected sound into an electronic format (e.g., an analog or digital format). The microphone array in FIG. 6 may include, for example, ten acoustic transducers: 620(A) and 620(B), which may be designed to be placed inside a corresponding ear of the user, acoustic transducers 620(C), 620(D), 620(E), 620(F), 620(G), and 620(H), which may be positioned at various locations on frame 610, and/or acoustic transducers 620(I) and 620(J), which may be positioned on a corresponding neckband 605.

In some embodiments, one or more of acoustic transducers 620(A)-(J) may be used as output transducers (e.g., speakers). For example, acoustic transducers 620(A) and/or 620(B) may be earbuds or any other suitable type of headphone or speaker.

The configuration of acoustic transducers 620 of the microphone array may vary. While augmented-reality system 600 is shown in FIG. 6 as having ten acoustic transducers 620, the number of acoustic transducers 620 may be greater or less than ten. In some embodiments, using higher numbers of acoustic transducers 620 may increase the amount of audio information collected and/or the sensitivity and accuracy of the audio information. In contrast, using a lower number of acoustic transducers 620 may decrease the computing power required by an associated controller 650 to process the collected audio information. In addition, the position of each acoustic transducer 620 of the microphone array may vary. For example, the position of an acoustic transducer 620 may include a defined position on the user, a defined coordinate on frame 610, an orientation associated with each acoustic transducer 620, or some combination thereof.

Acoustic transducers 620(A) and 620(B) may be positioned on different parts of the user's ear, such as behind the pinna, behind the tragus, and/or within the auricle or fossa. Or, there may be additional acoustic transducers 620 on or surrounding the ear in addition to acoustic transducers 620 inside the ear canal. Having an acoustic transducer 620 positioned next to an ear canal of a user may enable the microphone array to collect information on how sounds arrive at the ear canal. By positioning at least two of acoustic transducers 620 on either side of a user's head (e.g., as binaural microphones), augmented-reality system 600 may simulate binaural hearing and capture a 3D stereo sound field around about a user's head. In some embodiments, acoustic transducers 620(A) and 620(B) may be connected to augmented-reality system 600 via a wired connection 630, and in other embodiments acoustic transducers 620(A) and 620(B) may be connected to augmented-reality system 600 via a wireless connection (e.g., a BLUETOOTH connection). In still other embodiments, acoustic transducers 620(A) and 620(B) may not be used at all in conjunction with augmented-reality system 600.

Acoustic transducers 620 on frame 610 may be positioned in a variety of different ways, including along the length of the temples, across the bridge, above or below display devices 615(A) and 615(B), or some combination thereof. Acoustic transducers 620 may also be oriented such that the microphone array is able to detect sounds in a wide range of directions surrounding the user wearing the augmented-reality system 600. In some embodiments, an optimization process may be performed during manufacturing of augmented-reality system 600 to determine relative positioning of each acoustic transducer 620 in the microphone array.

In some examples, augmented-reality system 600 may include or be connected to an external device (e.g., a paired device), such as neckband 605. Neckband 605 generally represents any type or form of paired device. Thus, the following discussion of neckband 605 may also apply to various other paired devices, such as charging cases, smart watches, smart phones, wrist bands, other wearable devices, hand-held controllers, tablet computers, laptop computers, other external compute devices, etc.

As shown, neckband 605 may be coupled to eyewear device 602 via one or more connectors. The connectors may be wired or wireless and may include electrical and/or non-electrical (e.g., structural) components. In some cases, eyewear device 602 and neckband 605 may operate independently without any wired or wireless connection between them. While FIG. 6 illustrates the components of eyewear device 602 and neckband 605 in example locations on eyewear device 602 and neckband 605, the components may be located elsewhere and/or distributed differently on eyewear device 602 and/or neckband 605. In some embodiments, the components of eyewear device 602 and neckband 605 may be located on one or more additional peripheral devices paired with eyewear device 602, neckband 605, or some combination thereof.

Pairing external devices, such as neckband 605, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 600 may be provided by a paired device or shared between a paired device and an eyewear device, thus reducing the weight, heat profile, and form factor of the eyewear device overall while still retaining desired functionality. For example, neckband 605 may allow components that would otherwise be included on an eyewear device to be included in neckband 605 since users may tolerate a heavier weight load on their shoulders than they would tolerate on their heads. Neckband 605 may also have a larger surface area over which to diffuse and disperse heat to the ambient environment. Thus, neckband 605 may allow for greater battery and computation capacity than might otherwise have been possible on a stand-alone eyewear device. Since weight carried in neckband 605 may be less invasive to a user than weight carried in eyewear device 602, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 605 may be communicatively coupled with eyewear device 602 and/or to other devices. These other devices may provide certain functions (e.g., tracking, localizing, depth mapping, processing, storage, etc.) to augmented-reality system 600. In the embodiment of FIG. 6, neckband 605 may include two acoustic transducers (e.g., 620(I) and 620(J)) that are part of the microphone array (or potentially form their own microphone subarray). Neckband 605 may also include a controller 625 and a power source 635.

Acoustic transducers 620(I) and 620(J) of neckband 605 may be configured to detect sound and convert the detected sound into an electronic format (analog or digital). In the embodiment of FIG. 6, acoustic transducers 620(I) and 620(J) may be positioned on neckband 605, thereby increasing the distance between the neckband acoustic transducers 620(I) and 620(J) and other acoustic transducers 620 positioned on eyewear device 602. In some cases, increasing the distance between acoustic transducers 620 of the microphone array may improve the accuracy of beamforming performed via the microphone array. For example, if a sound is detected by acoustic transducers 620(C) and 620(D) and the distance between acoustic transducers 620(C) and 620(D) is greater than, e.g., the distance between acoustic transducers 620(D) and 620(E), the determined source location of the detected sound may be more accurate than if the sound had been detected by acoustic transducers 620(D) and 620(E).

Controller 625 of neckband 605 may process information generated by the sensors on neckband 605 and/or augmented-reality system 600. For example, controller 625 may process information from the microphone array that describes sounds detected by the microphone array. For each detected sound, controller 625 may perform a direction-of-arrival (DOA) estimation to estimate a direction from which the detected sound arrived at the microphone array. As the microphone array detects sounds, controller 625 may populate an audio data set with the information. In embodiments in which augmented-reality system 600 includes an inertial measurement unit, controller 625 may compute all inertial and spatial calculations from the IMU located on eyewear device 602. A connector may convey information between augmented-reality system 600 and neckband 605 and between augmented-reality system 600 and controller 625. The information may be in the form of optical data, electrical data, wireless data, or any other transmittable data form. Moving the processing of information generated by augmented-reality system 600 to neckband 605 may reduce weight and heat in eyewear device 602, making it more comfortable to the user.

Power source 635 in neckband 605 may provide power to eyewear device 602 and/or to neckband 605. Power source 635 may include, without limitation, lithium-ion batteries, lithium-polymer batteries, primary lithium batteries, alkaline batteries, or any other form of power storage. In some cases, power source 635 may be a wired power source. Including power source 635 on neckband 605 instead of on eyewear device 602 may help better distribute the weight and heat generated by power source 635.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 700 in FIG. 7, that mostly or completely covers a user's field of view. Virtual-reality system 700 may include a front rigid body 702 and a band 704 shaped to fit around a user's head. Virtual-reality system 700 may also include output audio transducers 706(A) and 706(B). Furthermore, while not shown in FIG. 7, front rigid body 702 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 600 and/or virtual-reality system 700 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 600 and/or virtual-reality system 700 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 600 and/or virtual-reality system 700 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device packaging medium, comprising:
a first layer of packaging laminate substrate material including a first plurality of vias formed therein; and
a second layer of packaging laminate substrate material having a second plurality of vias formed therein,
wherein the first plurality of vias stack with the second plurality of vias.

2. The semiconductor device packaging medium of claim 1, wherein the first plurality of vias and the second plurality of vias have a pitch in a range of forty to eighty micrometers.

3. The semiconductor device packaging medium of claim 1, wherein individual vias of the first plurality of vias and the second plurality of vias have a size in a range of ten to forty micrometers.

4. The semiconductor device packaging medium of claim 1, wherein individual vias of the first plurality of vias and the second plurality of vias have corresponding via pads each having a size in a range of twenty-five to sixty micrometers.

5. The semiconductor device packaging medium of claim 1, wherein a via stack that includes the first plurality of vias and the second plurality of vias is configured to connect a first system on chip positioned on a first side of the semiconductor device packaging medium to a second system on chip positioned on a second side of the semiconductor device packaging medium that is opposite the first side.

6. The semiconductor device packaging medium of claim 5, further comprising:
a plurality of peripheral stack vias configured to supply power and input-output routing to the first system on chip and the second system on chip.

7. The semiconductor device packaging medium of claim 5, wherein the first plurality of vias and the second plurality of vias are located only in a die to die interface region that is between the first system on chip and the second system on chip and that is smaller in area than the first system on chip and the second system on chip.

8. A semiconductor device package, comprising:
a first system on chip;
a second system on chip; and
a packaging laminate substrate positioned between the first system on chip and the second system on chip and including a via stack that is configured to provide direct via to via connection of the first system on chip to the second system on chip.

9. The semiconductor device package of claim 8, wherein the via stack has a pitch in a range of forty to eighty micrometers.

10. The semiconductor device package of claim 8, wherein individual vias of the via stack have a size in a range of ten to forty micrometers.

11. The semiconductor device package of claim 8, wherein the via stack is located only in a die to die interface region that is between the first system on chip and the second system on chip and that is smaller in area than the first system on chip and the second system on chip.

12. The semiconductor device package of claim 8, wherein the packaging laminate substrate further includes a plurality of peripheral stack vias configured to supply power and input-output routing to the first system on chip and the second system on chip.

13. The semiconductor device package of claim 8, wherein the first system on chip corresponds to an anchor die and the second system on chip corresponds to a chiplet that is smaller in area compared to the anchor die.

14. The semiconductor device package of claim 13, wherein the chiplet has a majority of power thereof supplied by the anchor die.

15. The semiconductor device package of claim 13, wherein the chiplet has a direct power supply through a ball grid array pad.

16. The semiconductor device package of claim 8, wherein the first system on chip is bonded face-to-face with the second system on chip with the via stack providing direct via to via connection therebetween.

17. A method, comprising:
forming a first layer of packaging laminate substrate material including a first plurality of vias formed therein;
forming a second layer of packaging laminate substrate material having a second plurality of vias formed therein; and
stacking the first plurality of vias with the second plurality of vias.

18. The method of claim 17, wherein the first plurality of vias and the second plurality of vias have a pitch in a range of forty to eighty micrometers.

19. The method of claim 17, wherein individual vias of the first plurality of vias and the second plurality of vias have a size in a range of ten to forty micrometers.

20. The method of claim 17, wherein individual vias of the first plurality of vias and the second plurality of vias have corresponding via pads each having a size in a range of twenty-five to sixty micrometers.
